(19) United States
(12) Patent Application Publication
(10) Pub. No.: US 2024/0347525 A1
(43) Pub. Date: Oct. 17, 2024

(54) APPARATUS INCLUDING STANDARD CELL

(71) Applicant: Micron Technology, Inc., Boise, ID (US)

(72) Inventors: Takamitsu Onda, Tokyo (JP); Tomohiro Kitano, Tokyo (JP)

(73) Assignee: Micron Technology, Inc., Boise, ID (US)

(21) Appl. No.: 18/604,217

(22) Filed: Mar. 13, 2024

Related U.S. Application Data
(60) Provisional application No. 63/495,383, filed on Apr. 11, 2023.

(51) Int. Cl. H01L 27/02; H01L 23/522; H01L 27/092

(52) U.S. Cl. CPC H01L 27/0207; H01L 23/5228; H01L 27/092

(57) ABSTRACT

According to one or more embodiments of the disclosure, an apparatus comprises: a semiconductor substrate including a first region, a second region, and a third region between the first region and the second region; and a plurality of wiring layers, at least in part, above the third region. The first region includes first transistors of first conductivity-type. The second region includes second transistors of second conductivity-type. The wiring layers include a lower wiring layer, a middle wiring layer, and an upper wiring layer. One or more wirings in the middle wiring layer elongate through the third region in a first direction to connect ones of sources and drains of the first transistors and corresponding ones of sources and drains of the second transistors. One or more wirings in the lower wiring layer elongate in the third region in a second direction perpendicular to the first direction to connect ones of the wirings of the middle wiring layer and corresponding ones of the wirings of the middle wiring layer.

### CROSS-REFERENCE TO RELATED APPLICATIONS

This application claims the filing benefit of U.S. Provisional Application No. 63/495,383, filed Apr. 11, 2023. This application is incorporated by reference herein in its entirety and for all purposes.

### BACKGROUND

A semiconductor apparatus may include a semiconductor device, such as a memory device. A semiconductor device or a memory device may be provided by a semiconductor chip formed on a semiconductor wafer. A semiconductor device or a semiconductor chip may include a layout design or a layout structure referred to as a standard cell. A standard cell includes a group of transistor and interconnect structures to provide circuit functions, such as logic functions and storage functions.

### BRIEF DESCRIPTION OF THE DRAWINGS

FIG. 1 depicts a schematic structure of a semiconductor device 100 in a plan view according to an embodiment of the disclosure.

FIGS. 2A-2E depict a schematic structure of a semiconductor device in a cross-sectional view according to an embodiment of the disclosure.

FIG. 3 depicts a schematic structure of a semiconductor device 100 in a plan view according to an embodiment of the disclosure.

FIGS. 4A-4D depict a schematic structure of a semiconductor device in a cross-sectional view according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

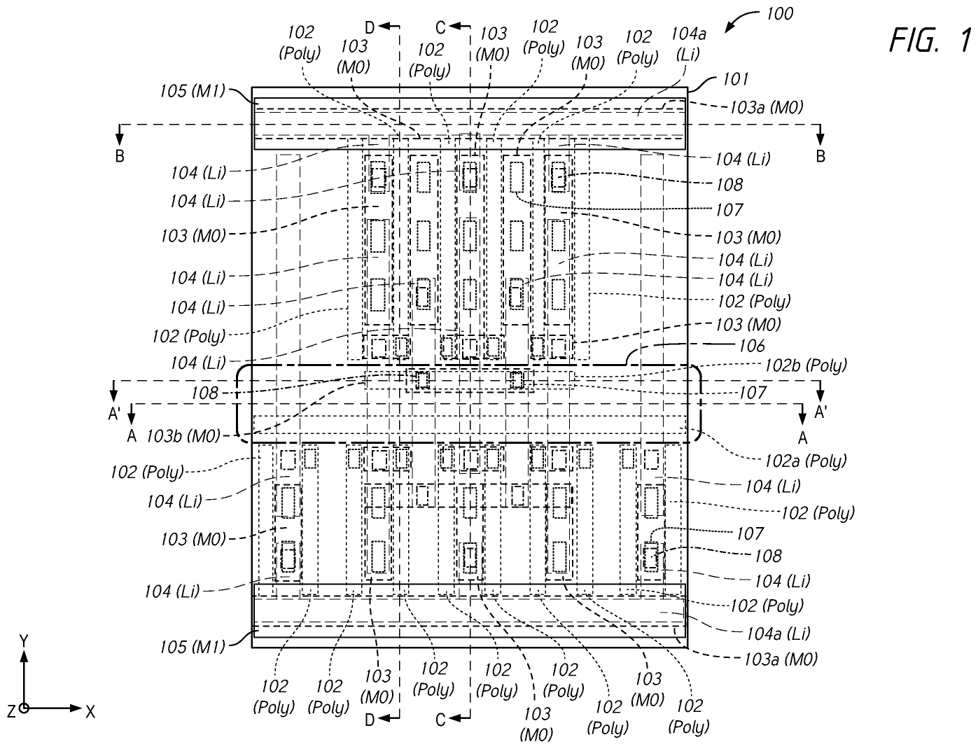

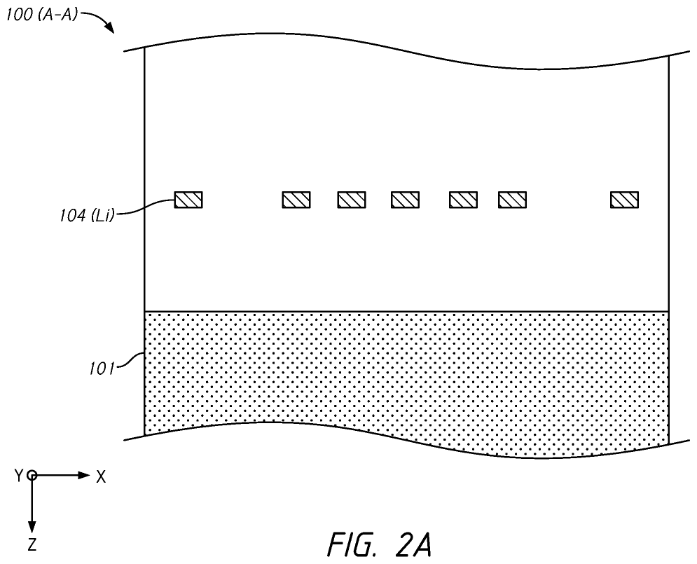

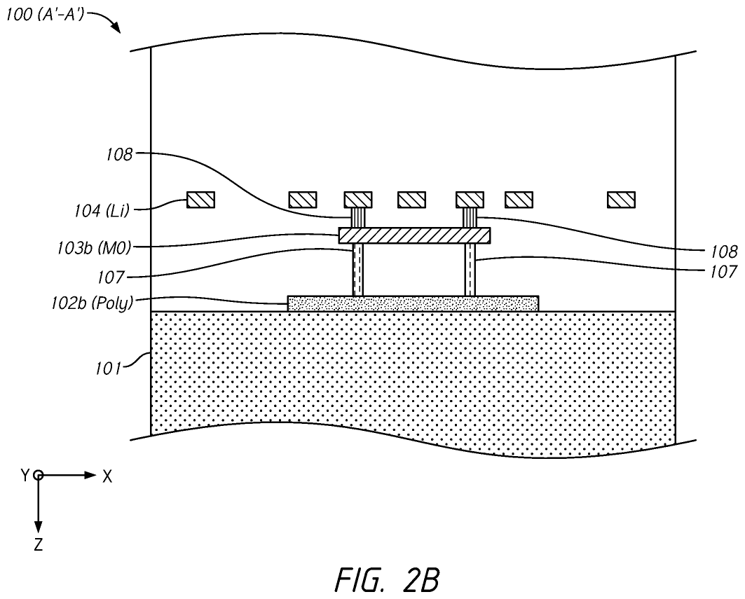

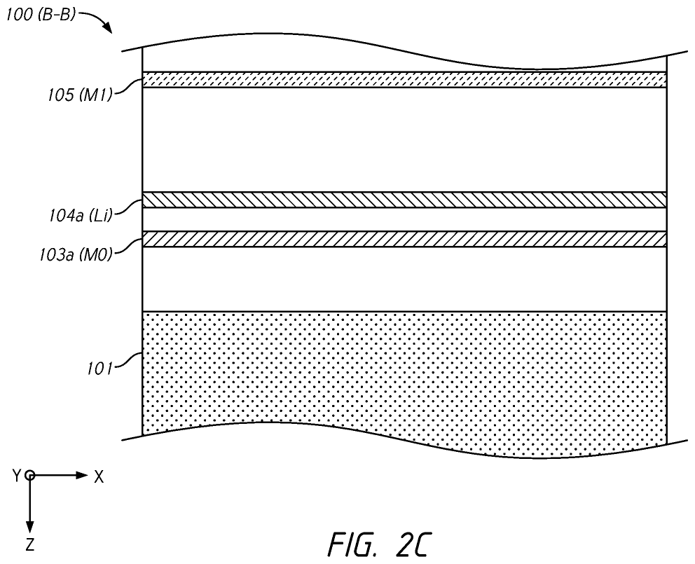

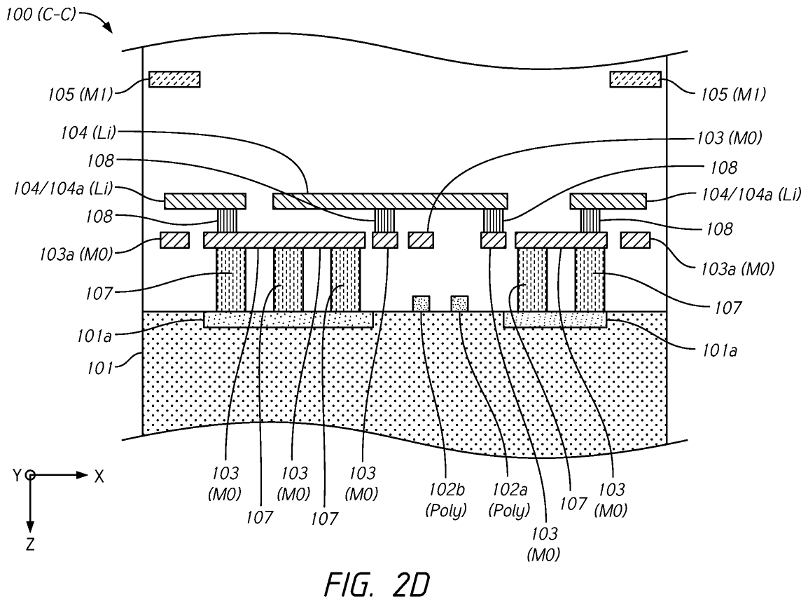

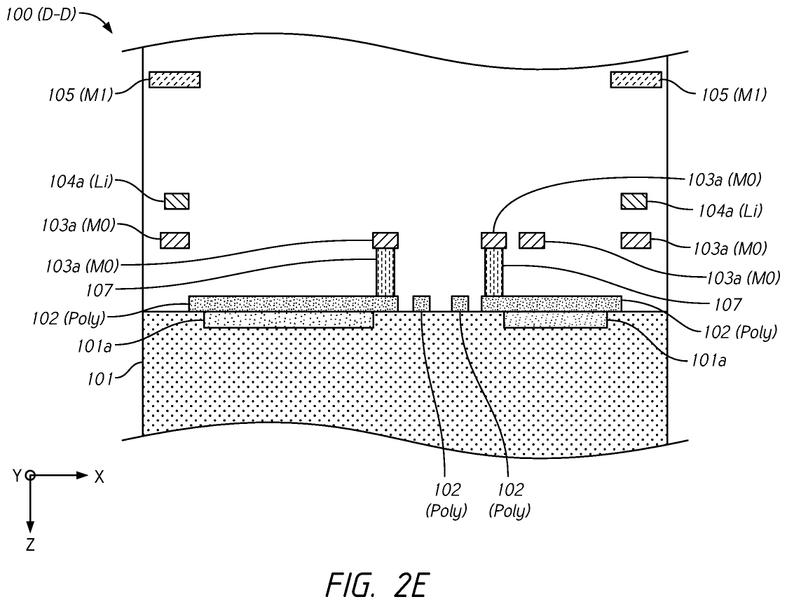

FIG. 1 depicts an example of a schematic structure of a semiconductor device 100 in a plan view according to an embodiment of the disclosure. FIGS. 2A-2C depict cross-sectional views of the schematic structure of the semiconductor device 100 at lines A-A, A′-A′, and B-B illustrated in FIG. 1, respectively, according to an embodiment of the disclosure. FIGS. 2D and 2E depict other cross-sectional views of the schematic structure of the semiconductor device 100 at lines C-C and D-D illustrated in FIG. 1, respectively, according to an embodiment of the disclosure. The semiconductor device 100 may be one example of or included in an apparatus or a semiconductor apparatus. The semiconductor device 100 may be provided by a semiconductor chip processed and formed on a semiconductor substrate 101 or a semiconductor wafer. The semiconductor device 100 or the semiconductor chip may include a layout design or a layout structure of a standard cell. A standard cell includes a standardized simple logic circuit that is repeatedly used in large quantities to form a plurality of chips on the wafer. A plurality of standard cells may be arranged next to each other and form a block of multiple logic circuits providing multiple circuit functions or a combination of circuit functions.

During fabrication, elements of each of individual circuits or components, such as transistors, resistors, and capacitors, may be formed on the semiconductor substrate 101 by a Front-End-Of-Line (FEOL) process. Various wirings or wiring layers may be formed to provide electrical connection or interconnection among the circuit elements and/or between different types of the individual components by a Middle-End-Of-Line (MEOL) (or Middle-Of-Line (MOL)) process and a Back-End-Of-Line (BEOL) process. The wirings, for example, may electrically connect gates, sources, and drains of the transistors with corresponding contacts to build circuit functions, such as inverter, NAND, and NOR. There may also be provided poly-layers serving as dummy layers to make the density around the transistor uniform to a certain extent to, for example, address local layer effects (LLE) where fluctuations in transistor characteristics occur due to non-uniform density of a diffusion layer or the like of the transistor.

Referring to FIG. 1 and FIGS. 2A-2E, the semiconductor device 100 according to the present embodiment include a plurality of wirings 102, 103, 104, and 105 formed in a plurality of corresponding wiring layers stacked on the semiconductor substrate 101. The example illustrates at least part of a layout of a standard cell having a NAND function by two transistors and the wirings. The two transistors may include a first transistor of a first conductivity-type and a second transistor of a second conductivity-type. In the example, the two transistors may be a p-channel metal-oxide-semiconductor (PMOS) transistor and an n-channel metal-oxide semiconductor (NMOS) transistor. The semiconductor substrate 101 or the standard cell on the semiconductor substrate 101 includes a first region and a second region as well as a third region 106. The first region includes the first transistor of the first conductivity-type. The second region includes the second transistor of the second conductivity-type. The first region may include a plurality of first transistors. The second region may include a plurality of second transistors. The third region 106 is between the first region and the second region in one horizontal direction (or a Y-direction along a Y-axis illustrated in the drawing, for example). The third region may not include any transistors. The third region may be configured to separate the first transistor(s) in the first region and the second transistor(s) in the second region. The third region may also be referred to as a transistor separation region. In the case of the first transistor being PMOS and the second transistor being NMOS or vice versa, the third region may also be referred to as a PN separation region. The standard cell is not limited to the present example and may have other functions or a combination of functions according to predetermined designs, specifications, or the like.

The plurality of wiring layers include a lower layer (or a lower wiring layer), a middle layer (or a middle wiring layer), and an upper layer (or an upper wiring layer). The lower layer may include a plurality of first lower layer wirings 102 and a plurality of second lower layer wirings 103. The middle layer may include a plurality of middle layer wirings 104. The upper layer may include a plurality of upper layer wirings 105. In the drawing, the upper layer wirings 105 are illustrated with a solid line to indicate that it is in the upper layer, which is the uppermost layer in the present example. The lower layer and middle layer wirings 102, 103 and 104 are illustrated with dotted lines to indicate that they are in the lower and middle layers. The wiring layers may be surrounded by or embedded in one or more insulating layers (not separately depicted). The insulating layers may be provided between the neighboring wirings.

The lower layer may have multiple layers that include the first lower layer wirings 102 and the second lower layer wirings 103, respectively. The layer for the first lower layer wirings 102 may be a poly-layer (which may be denoted as Poly). The layer for the second lower layer wiring 103 may be a metal layer (which may be denoted as M0). The transistor elements and structures may be formed by FEOL. The lower layer may be formed by MEOL/MOL. The lower layer Poly or its wirings 102 may include a material, such as doped poly silicon, with a relatively higher resistance value. The lower layer Poly may also include a metal material in addition to poly silicon to form a poly-metal layer structure. The poly-metal layer may provide a poly-metal gate. The lower layer M0 or its wirings 103 may include a metal material, such as tungsten.

The middle layer including the middle layer wirings 104 may be a metal layer (which may be denoted as Li). The middle layer may include more than one metal layers. The middle layer may be formed also by MEOL/MOL after the provision of the first metal layer M0. The second metal layer Li or its wirings 104 may include a metal material, such as tungsten. The metal material of the wirings 104 may be the same as or different from the metal material of the wirings 103.

The upper layer including the upper layer wirings 105 may be another metal layer (which may be denoted as M1). The upper layer may include more than one metal layers (M1, M2, and so on) stacked with one another, each of which includes one or more wirings. The upper layer M1 may be formed by BEOL. The upper layer M1 or its wirings 105 may include a metal material, such as cupper, with a relatively lower resistance value. The lower layer Poly and/or the lower layer M0 may have a resistance higher than the upper layer M1.

In the example, the plurality of upper layer wirings 105 include two wirings. One of the wirings 105 elongate in one horizontal direction (or an X-direction along an X-axis illustrated in the drawing, for example) at one end of another horizontal direction (or a Y-direction along a Y-axis illustrated in the drawing, for example) in the upper layer M1 in a plan view or in an X-Y plane. Another one of the wirings 105 elongates in the X direction at another end of the Y direction in the upper layer M1 in a plan view. The two wirings 105 are arranged in parallel at the opposite ends in the Y direction, and each runs from one end to another end of the upper layer M1 in the X direction. The X direction and the Y direction are perpendicular (or substantially perpendicular within reasonable tolerances of fabrication, measurement, etc.) to each other. The wirings 105 provide electrical connection or interconnection from the semiconductor device 100 to another semiconductor device (not separately depicted) arranged adjacently in the X direction. In the case where each of the semiconductor devices includes a standard cell, the wirings 105 electrically connect or couple one standard cell to another standard cell. The respective wirings 105 provide input and output from and to the neighboring standard cells. The number, the size, the position, or the like of the wirings 105 is not limited to the illustrated example and can be determined based on, for example, designs, specifications, or the like of the standard cells, the respective layers and wirings, the transistors, and such, as appropriate.

In the example, the plurality of middle layer wirings 104 include various pieces of wiring extending in the X direction and/or the Y direction in the middle layer Li in a plan view. At least some wirings of the third wirings 104 elongate through the PN separation region 106 in the Y direction. Referring to FIG. 2A, at the positions corresponding to those at line A-A in FIG. 1, the wirings 104 that elongates through the PN separation region 106 are arranged in parallel with and spaced apart from each other in the X direction. The areas or spaces between and around the wirings 104 in the first (X) and Y directions as well as in a vertical direction (or a Z-direction along a Z-axis illustrated in the drawing, for example) may be filled with an insulating layer or an insulating material. On opposite sides across the PN separation region 106 (which are the first and second regions) are the first transistor of the first conductivity-type, such as the PMOS transistor, and the second transistor of the second conductivity-type, such as the NMOS transistor. The PN separation region 106 separates a p-region of the PMOS transistor and an n-region of the NMOS transistor from each other. The wirings 104 that extend from one side to another side of the PN separation region 106 provide electrical connection or coupling between a source and a drain of the PMOS transistor and a corresponding source and a corresponding drain of the NMOS transistor in the Y direction. In the first and second regions separated by the PN separation region 106, there may be a plurality of PMOS transistors and a plurality of NMOS transistors, respectively.

In the example, the plurality of middle layer wirings 104 include two wirings 104a extending in the X direction at both ends of the Y direction in the middle layer Li. The wirings 104a are arranged in parallel at the opposite ends in the Y direction, and each runs from one end to another end of the middle layer Li in the X direction. The two wirings 104a are at positions in the middle layer Li corresponding to the positions of the two wirings 105 in the upper layer M1. For example, referring to FIG. 2C, one of the two wirings 104a at one end of the Y direction in the upper layer M1 corresponds to the position of one of the two wirings 105 in the upper layer M1. The wirings 104a provide electrical connection or interconnection from the semiconductor device 100 to another semiconductor device (not separately depicted) arranged adjacently in the X direction. In the case where each of the semiconductor devices includes a standard cell, the wirings 104a electrically connect or couple one standard cell to another standard cell. The respective wirings 104a may provide input and output from and to the neighboring standard cells. In another instance, the respective wirings 104a may be coupled to power sources or power supplies. The number, the size, the position, or the like of the wirings 104a is not limited to the illustrated example and can be determined based on, for example, designs, specifications, or the like of the standard cells, the respective layers and wirings, the transistors, and such, as appropriate. As the wirings 104a serve electrical routes in a similar manner to, but in a different layer from, the wirings 105, a greater number of wirings or electrical routes within multiple layers over a semiconductor substrate are available between the neighboring semiconductor devices or standard cells at least in one direction. For example, in a case if the layout size of the standard cell is reduced in the Y direction due to a change in the design standards or criteria to advance chip fabrication processing or chip downsizing, cell-to-cell interconnection will be further efficiently and effectively secured by the wirings in the multiple layers according to the present embodiment.

In the example, the plurality of lower layer wirings 103 include various pieces of wiring extending in the X direction and/or the Y direction in the lower layer M0 in a plan view. Referring to FIG. 2D, some of the wirings 103 are connected to, for example, active device regions in the semiconductor substrate 101 via a plurality of conductive contacts 107 extending in the Z direction between the lower layer M0 and a diffusion layer 101a of the semiconductor substrate 101. Also, some of the wirings 103 are connected to, for example, the wirings 104 in the middle layer Li via a plurality of contacts 108 extending between the two layers in the Z direction. Each of the contacts 108 may include a conductive material. The wirings 103 include two wirings 103a extending in the X direction at both ends of the Y direction in the lower layer M0. The wirings 103a are arranged in parallel at the opposite ends in the Y direction, and each runs from one end to another end of the lower layer M0 in the X direction. The two wirings 103a are at positions in the lower layer M0 corresponding to the positions of the two wirings 105 in the upper layer M1. For example, referring to FIG. 2C, one of the two wirings 103a at one end of the Y direction in the lower layer M0 corresponds to the position of one of the two wirings 105 in the upper layer M1. In a similar manner to the wirings 104a and the wirings 105, the wirings 103a provide electrical connection or interconnection from one semiconductor device/standard cell to another semiconductor device/standard cell in the X direction. The number, the size, the position, or the like of the wirings 103a is not limited to the illustrated example and can be determined based on, for example, designs, specifications, or the like of the standard cell, the respective layers and wirings, the transistors, and such, as appropriate. Accordingly, together with the wirings 104a in the middle layer Li and the wirings 105 in the upper layer M1, the wirings 103a in the lower layer M0 secure a further greater number of electrical routes between the neighboring semiconductor devices/standard cells and provide greater flexibility in wiring layout, which is further effective in chip downsizing.

In the example, the plurality of lower layer wirings 102 include various pieces of wiring extending in the X direction and the Y direction in the lower layer Poly in a plan view. In some embodiments, some of the wirings 102 in the lower layer Poly may be dummy wirings. The dummy wirings may be provided, for example, to make the density around the transistors uniform to a certain extent to address LLE where non-uniform density of diffusion layers of the transistors causes fluctuations of transistor characteristics. In the example, the wirings 102 include a wiring 102a provided in the PN separation region 106. The wiring 102a is arranged at a position within the PN separation region 106 when viewed from above. The wiring 102a extends in the X direction from one end to another end. Referring to FIG. 2D, the wiring 102a is provided on the semiconductor substrate 101. The spaces around the wiring 102a in the X and Y directions (as well as spaces between the semiconductor substrate 101 in the Z direction if any) may be filled with an insulating layer or an insulating material. In a similar manner to the wirings 103a in the other lower layer M0, the wiring 102a of the lower layer Poly in the PN separation region 106 add further interconnection of the neighboring semiconductor devices/standard cells in the X direction and provide further greater flexibility in wiring layout. The number, the size, the position, or the like of the wiring 102a is not limited to the illustrated example and can be adjusted based on, for example, designs, specifications, or the like of the standard cells, the respective layers and wirings, the transistors, and such, as appropriate.

In the PN separation region 106 of the example, there is another wiring 103b in the lower layer M0. The wiring 103b elongates in the X-direction. Referring to FIG. 2B, the wiring 103b of the lower layer M0 connects or couples, via a plurality of contacts 108, one or more of the wirings 104 of the middle layer M0 to corresponding one or more of the wirings 104. The wirings 104 run through the PN separation region 106 in the Y-direction when viewed from the above. The contacts 108 are provided at such positions in the PN separation region 106 that the wiring 103b provides electrical connection or coupling between the target wirings 104. Each of the contacts 108 may include a conductive material.

Further in the PN separation 106 of the example, there is another wiring 102b in the lower layer Poly. The wiring 102b elongates in the X-direction. Referring to FIG. 2B, the wiring 102b of the lower layer Poly is connected or coupled to the wiring 103b via a plurality of contacts 107. The plurality of contacts 107 are provided in alignment with the plurality of contacts 108 in the X-Y plane. The wiring 102b thus connects or couples the one or more of the wirings 104 to the corresponding one or more of the wirings 104 in the middle layer Li via the contacts 107, the wiring 103b, and the contacts 108. In another example, the wiring 103b may not be necessarily provided in the PN separation 106. The wiring 102b then provides the connection or coupling of the target wirings 104 without the wirings 103b.

The wirings 102b and the wiring 103b each in the lower layers Poly and M0 meet predetermined requirements in terms of resistance values even if the lower layers Poly and M0 or the wirings 102b and 103b thereof may have higher resistances than the upper layer M1 or the wirings 105. Accordingly, while maintaining the resistance values in a predetermined range, the wirings 102b and 103b provide, in the PN separation region 106, additional electrical routes of the wirings 104 of the middle layer Li that connect the transistors (such as the PMOS and NMOS transistors) on the one side (or the first region) and the other side (or the second region) of the PN separation region 106 (or the third region). This further effectively increases the wiring flexibility and achieves further effective use of the multiple wiring layers and the regions within the apparatus 100. The number, the size, the position, or the like of each of the wirings 102b and 103b is not limited to the illustrated example and can be determined based on, for example, designs, specifications, or the like of the PN separation region 106, the standard cells, the respective layers and wirings, the transistors, and such as appropriate.

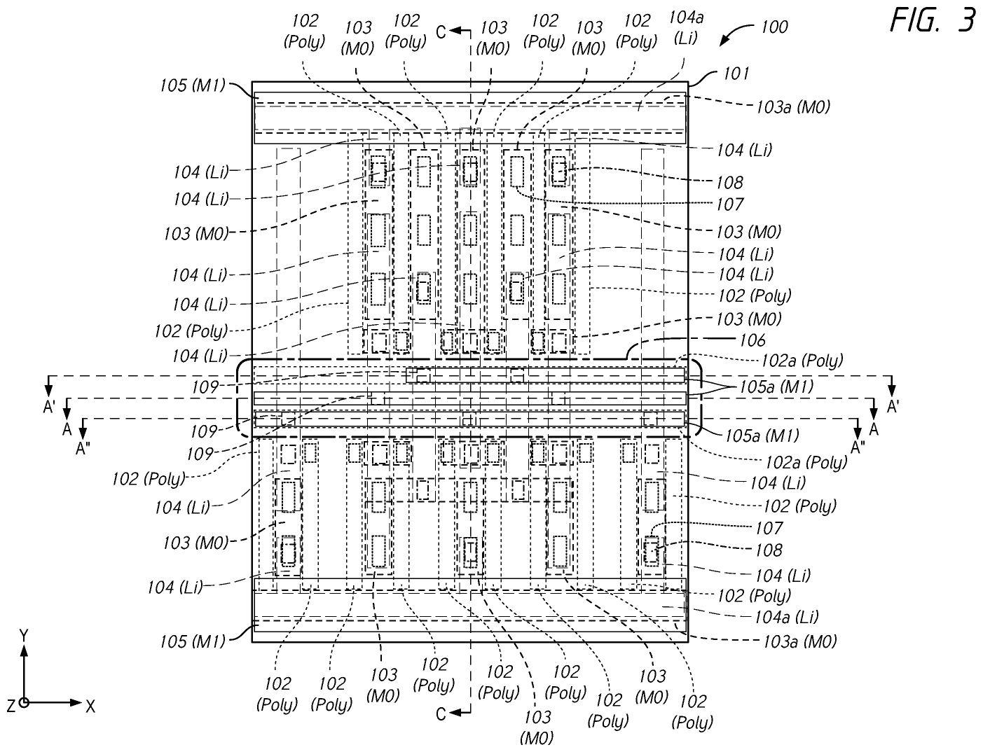

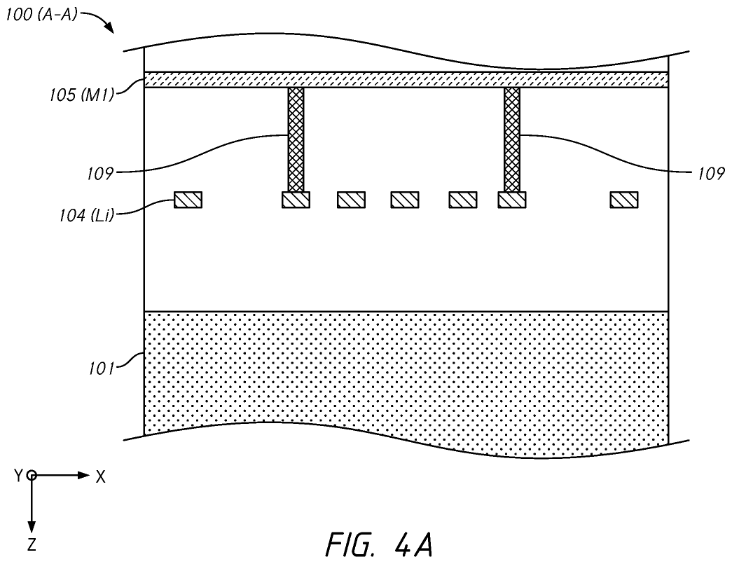

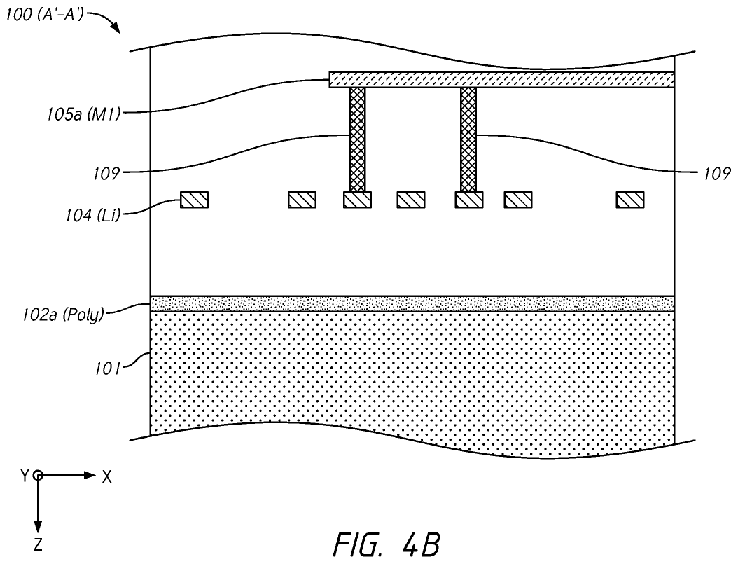

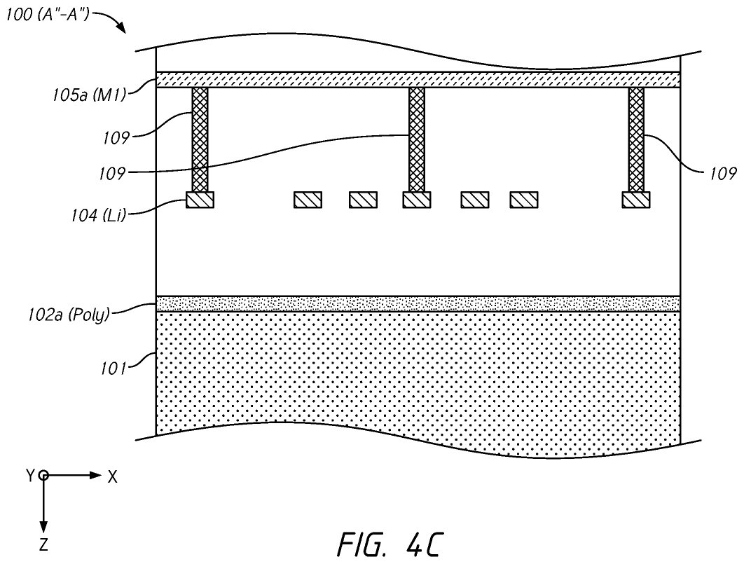

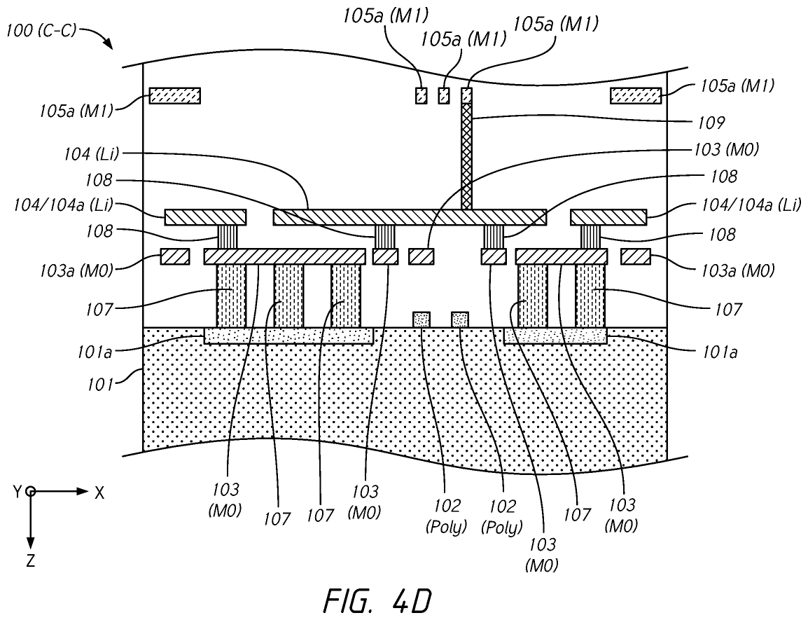

FIG. 3 depicts another example of a schematic structure of the semiconductor device 100 in a plan view according to an embodiment of the disclosure. FIGS. 4A-4D depict cross-sectional views of the schematic structure of the semiconductor device 100 at lines A-A, A′-A′, A″-A″ and C-C illustrated in FIG. 3, respectively, according to an embodiment of the disclosure.

While the PN separation region 106 of the apparatus 100 of FIG. 1 includes the wirings 102a and 102b and the wiring 103b in the lower layer Poly and the other lower layer M0, both of which may be provided by MEOL processes, the PN separation region 106 of the apparatus 100 of FIG. 3 includes additional wirings 105a in the upper layer M1. The wirings 105a may be provided in place of or in addition to the wirings 102a and 102b and the wirings 103b within the PN separation region 106. The wirings 105a may be provided by BEOL processes.

In a similar manner to the wirings 102a of the lower layer Poly, the wirings 105a may extend from one end to another end of the PN separation region 106 in the X-direction and may be used for interconnection between the neighboring semiconductor devices or standard cells. Such interconnection may provide input and output signal connections between the corresponding gates of the transistors of the respective standard cells. This way, a yet further greater number of wirings for device-to-device or cell-to-cell interconnection can be achieved while achieving further effective use of the PN separation region 106.

In a similar manner to the wirings 102b of the lower layer Poly and/or the wiring 103b of the other lower layer M0, the wirings 105a may be used for connecting/coupling the one or more of the wirings 104 to the corresponding one or more of the wirings 104 in the middle layer Li. Between the wirings 105a and the target wirings 104 are a plurality of contacts 109. The contacts 109 are provided at such positions in the PN separation region 106 that the wirings 105a provide electrical connection or coupling between the target wirings 104. Each of the contacts 109 may include a conductive material. The wirings 105a thus provide additional flexibility of electrical routes for the target wirings 104 that connect the transistors (such as the PMOS and NMOS transistors) on the one side (or the first region) and the other side (or the second region) of the PN separation region 106 (or the third region). This achieves further effective use of the PN separation region 106 within the apparatus 100. The number, the size, the position, or the like of the wirings 105a is not limited to the illustrated example and can be determined based on, for example, designs, specifications, or the like of the PN separation region 106, the standard cells, the respective layers and wirings, the transistors, and such, as appropriate.

According to the present embodiments, the semiconductor device 100 may provide a memory device. A memory device, for example, may include a plurality of memory banks that have a plurality of memory cells arranged in a matrix, one or more circuits that provide memory access functions, such as read operations and write operations to the memory banks/cells, and a control circuit that controls the circuits. One example of a memory device is a dynamic random access memory (DRAM). Other examples of a memory device include, but are not limited to, a static random-access memory (SRAM), a flash memory, an erasable programmable read-only memory (EPROM), a magnetoresistive random-access memory (MRAM), and a phase-change memory. In some embodiments, other examples of the semiconductor device, such as logic ICs (a microprocessor, an application-specific integrated circuit (ASIC) or the like), may also be applicable.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a semiconductor substrate including a first region, a second region, and a third region between the first region and the second region, the first region including a plurality of first transistors of first conductivity-type and a second region including a plurality of second transistors of second conductivity-type; and
a plurality of wiring layers, at least in part, above the third region, the plurality of wiring layers including a lower wiring layer, a middle wiring layer, and an upper wiring layer, wherein
a plurality of wirings in the middle wiring layer elongate through the third region in a first direction to connect ones of sources and drains of the plurality of first transistors and corresponding ones of sources and drains of the plurality of second transistors, and
one or more wirings in the lower wiring layer elongate in the third region in a second direction perpendicular to the first direction to connect ones of the wirings of the middle wiring layer and corresponding ones of the wirings of the middle wiring layer.

2. The apparatus according to claim 1, wherein
the plurality of wirings of the middle wiring layer are a plurality of first wirings,
the one or more wirings of the lower wiring layer are one or more second wirings, and
one or more third wirings in the lower wiring layer elongate in the third region in the second direction to connect ones of the first wirings of the middle wiring layer and corresponding ones of the first wirings of the middle wiring layer.

3. The apparatus according to claim 1, wherein
the plurality of wirings of the middle wiring layer are a plurality of first wirings,
the one or more wirings of the lower wiring layer are one or more second wirings, and
one or more third wirings in the upper wiring layer elongate in the third region in the second direction to connect ones of the first wirings of the middle wiring layer and corresponding ones of the first wirings of the middle wiring layer.

4. The apparatus according to claim 1, comprising at least two standard cells in the second direction, each of the standard cells including the semiconductor substrate and the plurality of wiring layers, wherein
the plurality of wirings of the middle wiring layer are a plurality of first wirings,
the one or more wirings of the lower wiring layer are one or more second wirings, and
one or more third wirings in at least one of the lower layer and the upper layer elongate in the second direction to connect the standard cells with each other.

5. The apparatus according to claim 4, wherein
one of the standard cells includes a NAND function, and
another of the standard cells includes a function the same as or different from the NAND function.

6. An apparatus, comprising at least two standard cells, each of the standard cells including:
a semiconductor substrate including a first region, a second region, and a third region between the first region and the second region, the first region including a plurality of first transistors of first conductivity-type and a second region including a plurality of second transistors of second conductivity-type; and
a plurality of wiring layers, at least in part, above the third region, the plurality of wiring layers including a lower wiring layer, a middle wiring layer, and an upper wiring layer, wherein
a plurality of first wirings in the middle wiring layer elongate through the third region in a first direction to connect ones of sources and drains of the plurality of first transistors and corresponding ones of sources and drains of the plurality of second transistors, and
one or more second wirings in the lower wiring layer elongate in the third region in a second direction perpendicular to the first direction to connect ones of the first wirings of the middle wiring layer and corresponding ones of the first wirings of the middle wiring layer, and wherein
one or more third wirings in at least one of the lower layer and the upper layer elongate in the second direction to connect the standard cells adjacent to each other in the second direction, one of the standard cells including a NAND function, and another of the standard cells including a function the same as or different from the NAND function.

7. The apparatus according to claim 6, wherein one or more fourth wirings in the lower wiring layer elongate in the third region in the second direction to connect ones of the first wirings of the middle wiring layer and corresponding ones of the first wirings of the middle wiring layer.

8. The apparatus according to claim 6, wherein one or more fourth wirings in the upper wiring layer elongate in the third region in the second direction to connect ones of the first wirings of the middle wiring layer and corresponding ones of the first wirings of the middle wiring layer.

9. An apparatus, comprising:
a first transistor in a first region;
a second transistor in a second region
a transistor separation region between the first region and the second region; and
a plurality of wiring layers including a lower layer, a middle layer, and an upper layer on a semiconductor substrate, wherein
the middle layer includes a wiring extending from the first region to the second region through the transistor separation region in a first direction to connect the first transistor to the second transistor, and
the lower layer includes a wiring extending in the transistor separation region in a second direction to provide connection with the wiring of the middle layer.

10. The apparatus according to claim 9, wherein
the wiring of the middle layer is a first wiring,
the wiring of the lower layer is a second wiring, and
the lower layer includes a third wiring extending in the transistor separation region in the second direction to connect the first wirings of the middle layer with each other.

11. The apparatus according to claim 9, wherein
the wiring of the middle layer is a first wiring,
the wiring of the lower layer is a second wiring, and
the upper layer includes a third wiring extending in the transistor separation region in the second direction to connect the first wirings of the middle wiring layer with each other.

12. The apparatus according to claim 9, wherein
the wiring of the middle layer is a first wiring,
the wiring of the lower layer is a second wiring, and
the lower layer and/or the upper layer includes a third wiring extending through the transistor separation region in the second direction to provide connection with another apparatus.

13. The apparatus according to claim 12, wherein,
the apparatus includes a standard cell, and
the third wiring connects the standard cell with another standard cell of the other apparatus in the second direction.

14. The apparatus according to claim 13, wherein the third wiring provides input and/or output signal connection between the standard cells.

15. The apparatus according to claim 9, wherein the first transistor includes a PMOS transistor, and the second transistor includes an NMOS transistor.

16. The apparatus according to claim 15, wherein the first wiring of the middle layer connects the PMOS transistor to the NMOS transistor.

17. The apparatus according to claim 9, wherein the lower layer has a resistance higher than the upper layer.

18. The apparatus according to claim 9, wherein
the lower layer includes poly silicon and/or tungsten,
the middle layer includes tungsten, and
the upper layer includes cupper.

19. The apparatus according to claim 9, wherein
the lower layer and the middle layer are provided by a MEOL process; and
the upper layer is provided by a BEOL process.

20. The apparatus according to claim 9, wherein the apparatus includes a memory device.
